(19) United States
(12) Patent Application Publication
(10) Pub. No.: US 2014/0273342 A1
(43) Pub. Date: Sep. 18, 2014

(54) VTH CONTROL METHOD OF MULTIPLE ACTIVE LAYER METAL OXIDE SEMICONDUCTOR TFT

(71) Applicant: Applied Materials, Inc., Santa Clara, CA (US)

(72) Inventors: Dong-Kil YIM, Santa Maria, CA (US); Rodney Shunleong LIM, Daly City, CA (US); Evelyn SCHEER, Stockstadt (DE); Tae Kyung WON, San Jose, CA (US); Soo Young CHOI, Fremont, CA (US); Harvey YOU, Mountain View, CA (US)

(73) Assignee: APPLIED MATERIALS, INC., Santa Clara, CA (US)

(21) Appl. No.: 14/201,532

(22) Filed: Mar. 7, 2014

Related U.S. Application Data
(60) Provisional application No. 61/780,734, filed on Mar. 13, 2013.

(51) Int. Cl. H01L 29/66

(52) U.S. Cl. CPC H01L 29/66742
USPC 438/104

(57) ABSTRACT

The present invention generally relates to TFTs and methods for fabricating TFTs. When multiple layers are used for the semiconductor material in a TFT, a negative Vth shift may result. By exposing the semiconductor layer to an oxygen containing plasma and/or forming an etch stop layer thereover, the negative Vth shift may be negated.

### CROSS-REFERENCE TO RELATED APPLICATIONS

This application claims benefit of U.S. Provisional Patent Application Ser. No. 61/780,734 (APPM/20682L), filed Mar. 13, 2013, which is herein incorporated by reference.

### BACKGROUND OF THE INVENTION

1. Field of the Invention

Embodiments of the present invention generally relate to a thin film transistor (TFT) and a method for manufacturing a TFT.

2. Description of the Related Art

Metal oxide semiconductors, such as zinc oxide (ZnO) and indium gallium zinc oxide (IGZO) are attractive for device fabrication due to their high carrier mobility, low processing temperatures, and optical transparency. TFTs made from metal oxide semiconductors (MO-TFTs) are particularly useful in active-matrix addressing schemes for optical displays. The low processing temperature of metal oxide semiconductors allows the formation of display backplanes on inexpensive plastic substrates such as polyethylene terephthalate (PET) and polyethylene naphthalate (PEN). The transparency of oxide semiconductor TFTs leads to improved pixel apertures and brighter displays.

While metal oxide semiconductors theoretically have high mobility, the actual mobility of the semiconductor layers can be an issue. Specifically, high mobility is theoretically possible for the semiconductor layer, but in practice, the mobility tends to be, at best, 10 cm²/V-sec, which is comparable to low temperature polysilicon.

Therefore, there is a need in the art for metal oxide TFTs that have a high mobility.

### SUMMARY OF THE INVENTION

The present invention generally relates to TFTs and methods for fabricating TFTs. When multiple layers are used for the semiconductor material in a TFT, a negative Vth shift may result. By exposing the semiconductor layer to an oxygen containing plasma and/or forming an etch stop layer thereover, the negative Vth shift may be negated.

In one embodiment, a method of fabricating a TFT comprises depositing a semiconductor layer over a substrate having a gate electrode and gate dielectric layer disposed thereon; exposing the semiconductor layer to an oxygen containing plasma; depositing an etch stop layer over the semiconductor layer; and forming source and drain electrodes over the etch stop layer.

In another embodiment, a method of fabricating a TFT comprises depositing a semiconductor layer over a substrate having a gate electrode and gate dielectric layer disposed thereon; depositing an etch stop layer over the semiconductor layer by a PECVD process comprising maintaining the substrate at a temperature of less than about 250 degrees Celsius, delivering an oxygen containing gas and a silicon containing gas in a ratio of oxygen containing gas to hydrogen containing gas of greater than 30:1, maintaining a chamber pressure of greater than about 1.25 Torr and delivering an RF power density of less than 3.34 kW/m²; and forming source and drain electrodes over the etch stop layer.

In another embodiment, a method of fabricating a TFT comprises depositing a semiconductor layer over a substrate having a gate electrode and gate dielectric layer disposed thereon; exposing the semiconductor layer to an oxygen containing plasma, wherein the exposing comprises forming a plasma from an oxygen containing gas selected from the group consisting of O₂, N₂O, O₃ and combinations thereof, wherein the exposing occurs at a pressure of less than 3 Torr, and wherein the plasma is ignited with an RF power density of greater than about 0.83 kW/m²; forming source and drain electrodes over the semiconductor layer; and depositing a passivation layer over the semiconductor layer and the source and drain electrodes.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 a cross-sectional view of a process chamber according to one embodiment.

FIGS. 2A-2C are schematic illustrations of a TFT 200 at various stages of production according to one embodiment.

FIG. 2D is a schematic illustration of a TFT 250 according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally relates to TFTs and methods for fabricating TFTs. When multiple layers are used for the semiconductor material in a TFT, a negative Vth shift may result. By exposing the semiconductor layer to an oxygen containing plasma and/or forming an etch stop layer thereover, the negative Vth shift may be negated.

The invention is illustratively described below utilized in a processing system, such as a plasma enhanced chemical vapor deposition (PECVD) system available from AKT America, a division of Applied Materials, Inc., located in Santa Clara, Calif. However, it should be understood that the invention has utility in other system configurations, including those sold by other manufacturers.

FIG. 1 is a schematic, cross sectional view of a process chamber that may be used to perform the operations described herein. The apparatus includes a chamber 100 in which one or more films may be deposited onto a substrate 120. The chamber 100 generally includes walls 102, a bottom 104 and a showerhead 106 which define a process volume. A substrate support 118 is disposed within the process volume. The process volume is accessed through a slit valve opening 108 such that the substrate 120 may be transferred in and out of the chamber 100. The substrate support 118 may be coupled to an actuator 116 to raise and lower the substrate support 118. Lift pins 122 are moveably disposed through the substrate support 118 to move a substrate to and from the substrate receiving surface. The substrate support 118 may also include heating and/or cooling elements 124 to maintain the substrate support 118 at a desired temperature. The substrate support 118 can also include RF return straps 126 to provide an RF return path at the periphery of the substrate support 118.

The showerhead 106 can be coupled to a backing plate 112 by a fastening mechanism 140. The showerhead 106 may be coupled to the backing plate 112 by one or more fastening mechanisms 140 to help prevent sag and/or control the straightness/curvature of the showerhead 106.

A gas source 132 can be coupled to the backing plate 112 to provide process gases through gas passages in the showerhead 106 to a processing area between the showerhead 106 and the substrate 120. The gas source 132 can include a silicon-containing gas supply source, an oxygen containing gas supply source, and a carbon-containing gas supply source, among others. Typical process gases useable with one or more embodiments include silane (SiH₄), disilane, N₂O, ammonia (NH₃), H₂, N₂ or combinations thereof.

A vacuum pump 110 is coupled to the chamber 100 to control the process volume at a desired pressure. An RF source 128 can be coupled through a match network 150 to the backing plate 112 and/or to the showerhead 106 to provide an RF current to the showerhead 106. The RF current creates an electric field between the showerhead 106 and the substrate support 118 so that a plasma may be generated from the gases between the showerhead 106 and the substrate support 118.

A remote plasma source 130, such as an inductively coupled remote plasma source 130, may also be coupled between the gas source 132 and the backing plate 112. Between processing substrates, a cleaning gas may be provided to the remote plasma source 130 so that a remote plasma is generated. The radicals from the remote plasma may be provided to chamber 100 to clean chamber 100 components. The cleaning gas may be further excited by the RF source 128 provided to the showerhead 106.

The showerhead 106 may additionally be coupled to the backing plate 112 by showerhead suspension 134. In one embodiment, the showerhead suspension 134 is a flexible metal skirt. The showerhead suspension 134 may have a lip 136 upon which the showerhead 106 may rest. The backing plate 112 may rest on an upper surface of a ledge 114 coupled with the chamber walls 102 to seal the chamber 100.

FIGS. 2A-2C are schematic cross-section illustrations of a TFT 200 at various stages of manufacture according to one embodiment. The TFT 200 includes a substrate 202, gate electrode 204, gate dielectric layer 206. A first semiconductor layer 208 and a second semiconductor layer 210 are also shown. It is to be understood that while two semiconductor layers are shown, additional semiconductor layers may be deposited.

Suitable materials that may be utilized for the substrate 202 include, but not limited to, silicon, germanium, silicon-germanium, soda lime glass, glass, semiconductor, plastic, steel or stainless steel substrates. Suitable materials for the gate electrode 204 include chromium, copper, aluminum, tantalum, titanium, molybdenum, and combinations thereof, or TCOs mentioned above. The gate electrode 204 may be formed by suitable deposition techniques, such as PVD followed by patterning through etching. Suitable materials that may be used for the gate dielectric layer 206 include silicon dioxide, silicon oxynitride, silicon nitride, aluminum oxide or combinations thereof. The gate dielectric layer 206 may be deposited by suitable deposition techniques including plasma enhanced chemical vapor deposition (PECVD).

The semiconductor layers 208, 210 may comprise metal oxides or metal oxynitrides. Examples of metal oxides and metal oxynitrides that may be used include indium-gallium-zinc oxide (IGZO), indium-titanium oxide (ITO), indium-zinc oxide (IZO), indium oxide, tin oxide, zinc oxide and zinc oxynitride.

TFTs with IGZO as the metal oxide semiconductor have shown limitations such as low mobility of ˜10 cm²/V-sec and bad controllability of the threshold voltage (Vth). A double (i.e., dual) active layer TFT with a thin IZO or ITO interface with the gate dielectric layer as a high mobility layer and bulk IGZO layer as a Vth control layer shows high mobility up to 100 cm²/Vsec and Vth of ˜0.5V. The mobility and Vth have a very strong dependency on the high mobility interface layer (IZO or ITO) thickness. When the thickness of the high mobility interface layer increases, the mobility is increased and Vth has a negative shift, which indicates that the thin high mobility interface layer thickness affects the TFT performance. In one embodiment, the thickness of thin high mobility interface layer may be about 50 Angstroms. Failure to control the high mobility interface layer thickness will lead to non-uniform mobility and a negative Vth shift. Large area substrates can be particularly challenging.

In order to obtain both high mobility and prevent a negative Vth shift, Applicants have developed a method to maintain a suitable Von (i.e., gate voltage at drain current of 1E-10 amp, similar term of Vth) around 0V by utilizing an oxygen containing plasma treatment and dielectric deposition (i.e., etch stop layer or passivation layer) by PECVD for double (i.e., dual) active layer TFTs with various thickness for the thin interface high mobility layer (i.e., IZO or ITO).

Metal oxide semiconductor TFT, such as those that contain IGZO, are very sensitive to the back channel in terms of TFT performance. Oxygen containing plasma on back channel surface of metal oxide semiconductor can make Von positive, relative to its original Von without oxygen plasma treatment. High pressure deposition of etch stop layer can make Von positive, relative to low pressure deposition.

The example discussed herein, semiconductor layer 208 comprises a high mobility metal oxide comprising ITO, IZO, indium oxide or tin oxide. It is to be understood that other metal oxides or oxynitrides may be utilized as well. Additionally, the second semiconductor layer 210 comprises IGZO but it is to be understood that other metal oxides or oxynitrides are contemplated as well. In one embodiment, the first semiconductor layer 208 has a thickness of between about 20 Angstroms to about 200 Angstroms.

Following the deposition of both semiconductor layers 208, 210, the topmost semiconductor layer 210 may be exposed to an oxygen containing plasma. The oxygen exposure may occur in a PECVD processing chamber, in particular, the same chamber utilized for an etch stop layer deposition as will be discussed below. When the same PECVD chamber is used for both oxygen plasma exposure and etch stop deposition, the substrate may remain in the chamber between processes.

The oxygen containing plasma treatment may occur by introducing or generating a plasma from an oxygen containing gas such as N₂O, O₂, O₃ or combinations thereof. The exposing occurs at a pressure of less than 3 Torr while applying an RF power density of greater than about 0.83 kW/m² to an electrode or showerhead.

In the embodiment shown in FIG. 2B, an etch stop 212 is formed over the oxygen treated semiconductor layer 210. The etch stop layer is formed by PECVD depositing an etch stop layer and then etching away a portion of the etch stop layer so that the etch stop 212 remains. In one embodiment, the etch stop 212 may be pattern deposited by PECVD. The etch stop layer may be deposited by maintaining the substrate at a temperature of less than about 250 degrees Celsius while introducing a silicon containing gas and an oxygen containing gas to form silicon oxide. In one embodiment, the silicon containing gas comprises silane and the oxygen containing gas comprises N₂O. The ratio of oxygen containing gas to silicon containing gas may be greater than about 30. The chamber may be maintained at a pressure of greater than about 1.25 Torr during deposition while an RF power density of less than 3.34 kW/m² is applied to an electrode or showerhead within the chamber.

It is to be understood that while the description herein is made with reference to having both an oxygen plasma treatment of the semiconductor layer 210 and deposition of an etch stop 212, it is contemplated that an oxygen containing plasma treatment may be used alone. Similarly, it is contemplated that the etch stop alone may be used without the presence of the oxygen containing plasma treatment.

After the etch stop 212 is formed, source and drain electrodes 214, 216 are formed. Suitable materials for the source and drain electrodes 214, 216 include chromium, copper, aluminum, tantalum, titanium, molybdenum, and combinations thereof, or TCOs mentioned above. The source and drain electrodes 214, 216 may be formed by suitable deposition techniques, such as PVD followed by patterning through etching.

In the case of back channel etch TFT, this method can be used after back channel etch process for passivation. FIG. 2D illustrates a TFT 250 having no etch stop, but rather, a passivation layer 218 formed over the exposed semiconductor layer 210 (i.e., the active channel) and the source and drain electrodes 214, 216. In the case of a back channel etch TFT, the oxygen containing plasma treatment discussed herein is utilized and the passivation layer is deposited while maintaining the substrate at a temperature of less than about 250 degrees Celsius while introducing a silicon containing gas and an oxygen containing gas to form silicon oxide. In one embodiment, the silicon containing gas comprises silane and the oxygen containing gas comprises N₂O. The ratio of oxygen containing gas to silicon containing gas may be greater than about 30. The chamber may be maintained at a pressure of greater than about 1.25 Torr during deposition while an RF power density of less than 3.34 kW/m² is applied to an electrode or showerhead within the chamber.

The Von of the multiple layer metal oxide semiconductor TFT can be maintained at suitable Von like −1V˜2V with 1st high mobility layer 20˜200 A thickness based upon using the oxygen containing plasma treatment and/or the etch stop. The thickness of the 1st high mobility layer (i.e., semiconductor layer 208) can be increased to greater than 50 Angstroms. The increased thickness of semiconductor layer 208 can be deposited with better control/uniformity of film thickness. As results, multiple layer metal oxide semiconductor TFTs can be fabricated with uniform and repeatable TFT performance as well as high mobility.

While the foregoing is directed to embodiments of the present invention, other and further embodiments of the invention may be devised without departing from the basic scope thereof, and the scope thereof is determined by the claims that follow.

1. A method of fabricating a thin film transistor, comprising:
depositing a semiconductor layer over a substrate having a gate electrode and gate dielectric layer disposed thereon;
exposing the semiconductor layer to an oxygen containing plasma;
depositing an etch stop layer over the semiconductor layer; and
forming source and drain electrodes over the etch stop layer.

2. The method of claim 1, wherein the semiconductor layer comprises a metal oxide.

3. The method of claim 2, wherein the metal oxide is selected from the group consisting of indium gallium zinc oxide, zinc oxide, zinc oxynitride, indium zinc oxide, indium titanium oxide, tin oxide, and combinations thereof.

4. The method of claim 1, wherein the semiconductor layer comprises multiple layers.

5. The method of claim 4, wherein the multiple layers comprise a first metal oxide layer and a second metal oxide layer and wherein the first metal oxide layer and the second metal oxide layer have at least one different feature selected from composition or properties, and wherein the first metal oxide layer has a thickness of between about 20 Angstrom and about 200 Angstroms and the first metal oxide layer thickness is less than the second metal oxide layer thickness.

6. The method of claim 1, wherein exposing the semiconductor layer to an oxygen plasma comprises forming a plasma from an oxygen containing gas selected from the group consisting of O₂, N₂O, O₃ and combinations thereof.

7. The method of claim 6, wherein exposing occurs at a pressure of less than 3 Torr.

8. The method of claim 7, wherein the plasma is ignited with an RF power density of greater than about 0.83 kW/m².

9. The method of claim 8, wherein the etch stop layer is formed by a PECVD process.

10. The method of claim 9, wherein the PECVD process comprises maintaining the substrate at a temperature of less than about 250 degrees Celsius, delivering an oxygen containing gas and a silicon containing gas in a ratio of oxygen containing gas to silicon containing gas of greater than 30:1, maintaining a chamber pressure of greater than about 1.25 Torr and delivering an RF power density of less than 3.34 kW/m².

11. The method of claim 1, wherein the etch stop layer is formed by a PECVD process.

12. The method of claim 11, wherein the PECVD process comprises maintaining the substrate at a temperature of less than about 250 degrees Celsius, delivering an oxygen containing gas and a silicon containing gas in a ratio of oxygen containing gas to silicon containing gas of greater than 30:1, maintaining a chamber pressure of greater than about 1.25 Torr and delivering an RF power density of less than 3.34 kW/m².

13. A method of fabricating a thin film transistor, comprising:
depositing a semiconductor layer over a substrate having a gate electrode and gate dielectric layer disposed thereon;
depositing an etch stop layer over the semiconductor layer by a PECVD process comprising maintaining the substrate at a temperature of less than about 250 degrees Celsius, delivering an oxygen containing gas and a silicon containing gas in a ratio of oxygen containing gas to silicon containing gas of greater than 30:1, maintaining a chamber pressure of greater than about 1.25 Torr and delivering an RF power density of less than 3.34 kW/m²; and
forming source and drain electrodes over the etch stop layer.

14. The method of claim 13, wherein the metal oxide is selected from the group consisting of indium gallium zinc oxide, zinc oxide, zinc oxynitride, indium zinc oxide, indium titanium oxide, tin oxide, and combinations thereof.

15. The method of claim 13, wherein the semiconductor layer comprises multiple layers.

16. The method of claim 15, wherein the multiple layers comprise a first metal oxide layer and a second metal oxide layer and wherein the first metal oxide layer and the second metal oxide layer have at least one different feature selected from composition or properties.

17. A method of fabricating a back channel etch thin film transistor, comprising:
depositing a semiconductor layer over a substrate having a gate electrode and gate dielectric layer disposed thereon;
exposing the semiconductor layer to an oxygen containing plasma, wherein the exposing comprises forming a plasma from an oxygen containing gas selected from the group consisting of O₂, N₂O, O₃ and combinations thereof, wherein the exposing occurs at a pressure of less than 3 Torr, and wherein the plasma is ignited with an RF power density of greater than about 0.83 kW/m²;
forming source and drain electrodes over the semiconductor layer; and
depositing a passivation layer over the semiconductor layer and the source and drain electrodes.

18. The method of claim 17, wherein the metal oxide is selected from the group consisting of indium gallium zinc oxide, zinc oxide, zinc oxynitride, indium zinc oxide, indium titanium oxide, tin oxide, and combinations thereof.

19. The method of claim 17, wherein the semiconductor layer comprises multiple layers.

20. The method of claim 19, wherein the multiple layers comprise a first metal oxide layer and a second metal oxide layer and wherein the first metal oxide layer and the second metal oxide layer have at least one different feature selected from composition or properties.
